(19) United States
(12) Patent Application Publication
(10) Pub. No.: US 2005/0199944 A1
(43) Pub. Date: Sep. 15, 2005

(54) [NON-VOLATILE MEMORY CELL]

(76) Inventors: Tung-Sheng Chen, Taoyuan County (TW); Chin-Hsing Kao, Taoyuan County (TW); Kuo-Hong Wu, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/709,263

(22) Filed: Apr. 26, 2004

(30) Foreign Application Priority Data
Mar. 11, 2004 (TW) 93106429

(51) Int. Cl. H01L 29/76

(52) U.S. Cl. 257/324; 257/321; 257/314; 257/315

(57) ABSTRACT

The present invention provides a non-volatile memory cell, comprising a tunnel dielectric layer disposed on the substrate, a barrier dielectric layer disposed over the tunnel dielectric layer, a graded charge trapping layer disposed between the tunnel dielectric layer and the barrier dielectric layer, a gate conductive layer disposed on the barrier dielectric layer and a source/drain region disposed in the substrate. The compositional ratio of the graded trapping layer gradually varies in different positions of the graded trapping layer.

### CROSS REFERENCE TO RELATED APPLICATIONS

This application claims the priority benefit of Taiwan application serial no. 93106429, filed Mar. 11, 2004.

### BACKGROUND OF INVENTION

1. Field of Invention

The present invention relates to a memory. More particularly, the present invention relates to a non-volatile memory cell.

2. Description of Related Art

The electrically erasable programmable read-only memory (EEPROM) devices allow multiple and repetitive writing, reading and erasure operations, and the storage data are retained even after the power supply is discontinued. Because of the aforementioned advantages, the EEPROM memory devices have become the mainstream non-volatile memory devices, which are widely applied in the electronic products, such as, personal computers and digital electronic products.

So far, according to the commonly adopted technology for fabricating the EEPROM memory, doped polysilicon is used to form the floating gate and the control gate of the EEPROM memory cell. A silicon oxide dielectric layer is disposed between the floating gate and the control gate, while a tunnel oxide layer is disposed between the floating gate and the substrate. As the memory is programmed, charges injected into the floating gate distribute evenly over the whole polysilicon floating gate layer. However, if defects exist in the underlying tunnel oxide layer, leakage currents may occur from the polysilicon floating gate, thus deteriorating the reliability of the device.

For solving the above problems, a silicon nitride trapping layer is employed to replace the polysilicon floating gate, and the upper and lower silicon oxide layers and the silicon nitride trapping layer sandwiched in-between constitute a silicon oxide/silicon nitride/silicon oxide (ONO) stacked structure. Since the silicon nitride trapping layer is not conductive, the trapped charges simply localize in specific regions, rather than distributing evenly over the whole layer. Therefore, when compared to the non-volatile memory device having the polysilicon floating gate, the non-volatile memory device of the ONO structure has higher tolerance toward the defects in the tunnel oxide layer and lower possibilities of leakage currents.

It is noted that the trapping efficiency of charges is closely related to the properties of the silicon nitride trapping layer. That is, whether charges can be easily trapped and whether the trapped charges can be readily escaped, is decided by the ratio of nitrogen content to silicon content for the silicon nitride trapping layer. The typical compositional ratio of nitrogen to silicon is 4:3 for the silicon nitride trapping layer, and the deep trapping levels of the silicon nitride trapping layer are not easily assessable to the charges, which decreases the charge trapping efficiency. Moreover, it is also difficult for the charges trapped in the deep trapping levels after multiple and repetitive writing to escape, thus degrading the reliability of the memory device.

In U.S. Pat. No. 6,406,960B1, a method of forming a silicon oxide/silicon nitride/silicon oxide (ONO) stacked structure having a silicon-rich silicon nitride trapping layer is disclosed. However, with uniform silicon-rich silicon nitride, the trapping levels of the trapping layer are shallow and has a high de-trapping rate.

As disclosed in U.S. Publication No. 2003/0190821 A1, a nitrogen-rich silicon nitride buffer layer is formed between the MOS gate structure and the silicon substrate as the barrier layer. The silicon-rich silicon nitride buffer layer, with trapping levels of high band gaps, offers a higher ability of trapping charges. Since the silicon rich silicon nitride layer traps charges, degradation of the gate oxide layer by the tunneling charges can be avoided.

Nonetheless, up to now, none of the existing non-volatile memory structures can solve the prior art problems and provide a trapping layer of high charge trapping efficiency.

### SUMMARY OF INVENTION

Accordingly, the present invention provides a non-volatile memory cell and the non-volatile memory structure, having a charge trapping layer with a high charge trapping efficiency.

Accordingly, the present invention provides a non-volatile memory cell and the non-volatile memory structure thereof by employing a graded charge trapping layer, which allows larger starting voltage detection windows, affords better endurance of repeated program/erase as well as read operations, and permits enhanced retention of data storage. Also, the non-volatile memory cell and the non-volatile memory structure thereof can be operated under a lower operation voltage and with less power consumption and is beneficial for the multi-bit design.

As embodied and broadly described herein, the invention provides a non-volatile memory cell, comprising a tunnel dielectric layer disposed on the substrate, a barrier dielectric layer disposed over the tunnel dielectric layer, a graded trapping layer disposed between the tunnel dielectric layer and the barrier dielectric layer, a gate conductive layer disposed on the barrier dielectric layer and a source/drain region disposed in the substrate.

As embodied and broadly described herein, the compositional ratio of the graded trapping layer varies from one side the graded trapping layer adjacent to the tunnel dielectric layer to the other side of the graded trapping layer adjacent to the barrier dielectric layer. By using the graded charge trapping layer with graded compositional ratios, the charge trapping efficiency is thus enhanced.

As embodied and broadly described herein, the graded trapping layer has a graded band gap and the graded band gap includes a plurality of trapping levels. The numbers of the trapping levels vary in different positions of the graded trapping layer, varying from one side of the graded trapping layer adjacent to the tunnel dielectric layer to the other side the graded trapping layer adjacent to the barrier dielectric layer. For different positions of the graded trapping layer, the position(s) with the narrower bandgap exhibits the higher potential barrier and allows carriers (charges) to go deep into the trapping layer by lateral hopping. By using the graded charge trapping layer with the graded band gap, the charge trapping efficiency is thus enhanced.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of the structure of a non-volatile memory cell according to the first preferred embodiment of this invention.

FIG. 2 is a schematic view of the band gap diagram for the structure of FIG. 1.

FIG. 3 is a schematic cross-sectional view of the structure of a non-volatile memory cell according to the second preferred embodiment of this invention.

FIG. 4 is a schematic view of the band gap diagram for the structure of FIG. 3.

FIG. 5 is a schematic cross-sectional view of the structure of a non-volatile memory cell according to the third preferred embodiment of this invention.

FIG. 6 is a schematic view of the band gap diagram for the structure of FIG. 5.

FIG. 7 is a schematic cross-sectional view of the structure of a non-volatile memory cell according to the fourth preferred embodiment of this invention.

FIG. 8 is a schematic view of the band gap diagram for the structure of FIG. 7.

FIGS. 9A to 9C illustrates cross-sectional views of the process steps for forming a non-volatile memory cell according to one preferred embodiment of this invention.

FIG. 10 is a graph showing the relation of threshold voltage (V) versus time (second) for the non-volatile memory.

FIG. 11 is a graph showing the relation of threshold voltage (V) versus time (second) for the non-volatile memory.

FIG. 12 is a graph showing the relation of threshold voltage (V) versus numbers of program/erase (P/E) cycles for the non-volatile memory.

FIG. 13 is a graph showing the relation of threshold voltage (V) versus time (second) for the non-volatile memory.

FIG. 14 is a graph showing the read-disturb characteristic of threshold voltage (V) versus time (second) for the non-volatile memory.

### DETAILED DESCRIPTION

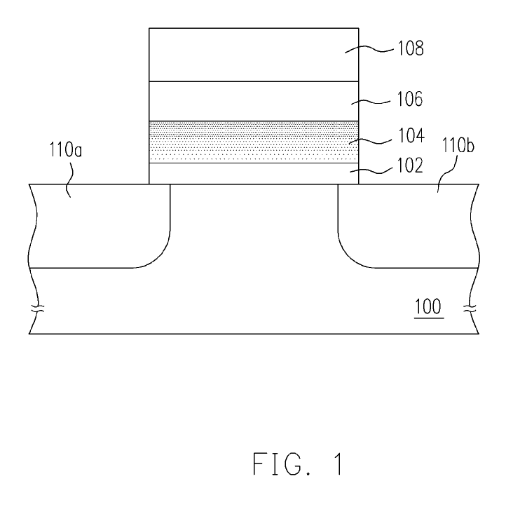

FIG. 1 is a schematic cross-sectional view of the structure of a non-volatile memory cell according to the first preferred embodiment of this invention.

Referring to FIG. 1, the non-volatile memory cell includes a substrate 100, a tunnel dielectric layer 102, a graded trapping layer 104, a barrier dielectric layer 106, a gate conductive layer 108 and a source region 110a/drain region 110b.

The substrate 100 is, for example, a silicon substrate. The substrate can be a P-type substrate or a N-type substrate.

The tunnel dielectric layer 102, for example, made of silicon oxide or other materials, is disposed on the substrate 100, while the barrier dielectric layer 106, for example, made of silicon oxide or other materials, is disposed over the tunnel dielectric layer 102.

The graded trapping layer 104 is disposed between the tunnel dielectric layer 102 and the barrier dielectric layer 106. The graded trapping layer 104, for example, has a thickness of about 50 Angstroms. The graded trapping layer 104 is not a homogeneous layer of the same composition. The compositional ratio of the graded trapping layer 104 in different positions varies, varying from the bottom side (the side adjacent to the tunnel dielectric layer 102) to the top side (the side adjacent to the barrier dielectric layer 106). For example, the compositional ratio of the graded trapping layer 104 becomes smaller from the bottom side to the top side.

The gate conductive layer 108, for example, made of polysilicon, doped polysilicon or other suitable conductive materials, is disposed on the barrier dielectric layer 106.

The source region 110a and the drain region 110b are disposed in the substrate 100 along both sides of the gate conductive layer 108. The source/drain regions 110a/110b are doped with either N-type dopants or P-type dopants.

According to the first embodiment, the compositional ratio of the graded trapping layer 104 becomes smaller from the bottom side to the top side. The graded trapping layer 104 is a graded silicon nitride layer (SiₓN_{y}) layer, for example. The silicon/nitrogen compositional ratio x/y of the graded silicon nitride layer decreases from the bottom side (the side adjacent to the tunnel dielectric layer 102) to the top side (the side adjacent to the barrier dielectric layer 106). The bottom side (the side adjacent to the tunnel dielectric layer 102) of the graded silicon nitride layer 104 includes silicon-rich silicon nitride, while the top side (the side adjacent to the barrier dielectric layer 106) of the graded silicon nitride layer 104 includes nitrogen-rich silicon nitride. The silicon/nitrogen compositional ratio x/y of silicon-rich silicon nitride is larger than ¾, while the silicon/nitrogen compositional ratio x/y of nitrogen-rich silicon nitride is smaller than ¾. In the middle portion of the graded silicon nitride layer 104, the silicon/nitrogen compositional ratio x/y is about ¾.

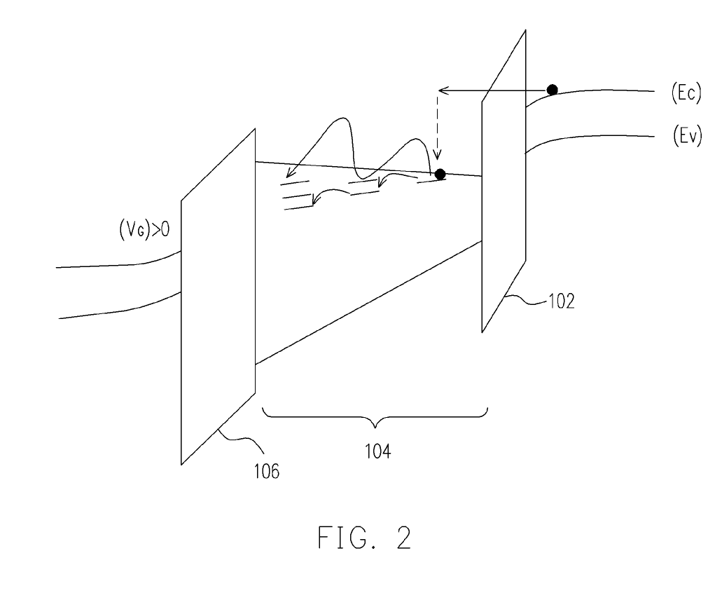

Because silicon nitride in the top side (the side adjacent to the barrier dielectric layer 106) of the graded silicon nitride layer 104 is nitrogen-rich silicon nitride, more trapping levels are available and accessible for charges. On the other hand, since silicon nitride in the bottom side (the side adjacent to the tunnel dielectric layer 102) of the graded silicon nitride layer 104 is silicon-rich silicon nitride, the potential barrier height between silicon nitride and the tunnel dielectric material is increased by increasing the silicon content in silicon nitride. Therefore, the graded silicon nitride layer 104 has a graded energy band gap. As shown in FIG. 2, as charges tunnel through the tunnel dielectric layer 102 and enters into the bottom side of the graded silicon nitride layer 104, charges are trapped by shallow trapping levels and then transferred to adjacent deeper trapping levels in the top side of the graded silicon nitride layer 104 by lateral hopping. Since the charges are trapped by deeper levels in the top side of the graded silicon nitride layer 104, they will not escape to the barrier dielectric layer 106. Moreover, due to the higher silicon content of silicon-rich silicon nitride in the bottom side of the graded silicon nitride layer 104, the increased potential barrier height reduces the back-tunneling possibility of the charges, thus increasing the charge trapping efficiency of the graded silicon nitride layer 104.

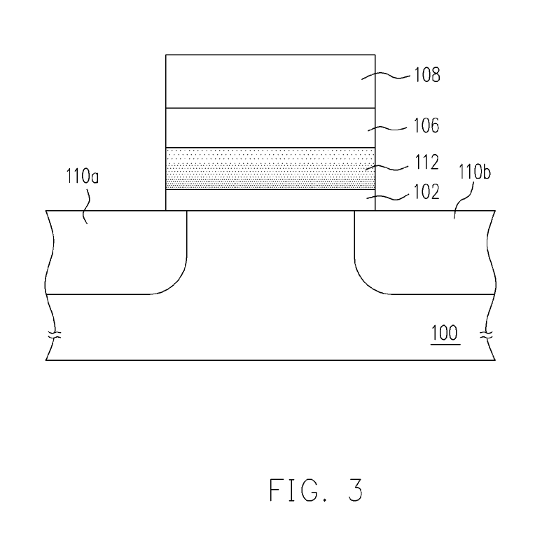

According to the second embodiment, the graded trapping layer 112 as shown in FIG. 3 is not a homogeneous layer of the same composition. The compositional ratio of the graded trapping layer 112 becomes larger from the bottom side (the side adjacent to the tunnel dielectric layer 102) to the top side (the side adjacent to the barrier dielectric layer 106). The graded trapping layer 112 is a graded silicon nitride layer (SiₓN_{y}) layer, for example. The silicon/nitrogen compositional ratio x/y of the graded silicon nitride layer increases from the bottom side (the side adjacent to the tunnel dielectric layer 102) to the top side (the side adjacent to the barrier dielectric layer 106). The bottom side (the side adjacent to the tunnel dielectric layer 102) of the graded silicon nitride layer 112 includes nitrogen-rich silicon nitride, while the top side (the side adjacent to the barrier dielectric layer 106) of the graded silicon nitride layer 112 includes silicon-rich silicon nitride. The silicon/nitrogen compositional ratio x/y of silicon-rich silicon nitride is larger than 3/4, while the silicon/nitrogen compositional ratio x/y of nitrogen-rich silicon nitride is smaller than ¾. In the middle portion of the graded silicon nitride layer 112, the silicon/nitrogen compositional ratio x/y is about ¾.

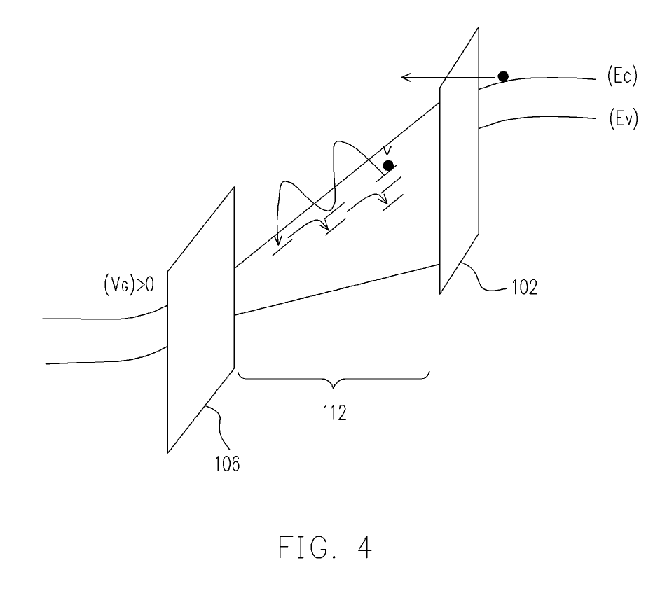

Because silicon nitride in the top side (the side adjacent to the barrier dielectric layer 106) of the graded silicon nitride layer 112 is silicon-rich silicon nitride, the potential barrier height between silicon nitride and the barrier dielectric material is increased. On the other hand, since silicon nitride in the bottom side (the side adjacent to the tunnel dielectric layer 102) of the graded silicon nitride layer 112 is nitrogen-rich silicon nitride, more trapping levels are available. Therefore, the graded silicon nitride layer 112 has a graded energy band gap. As shown in FIG. 4, as charges tunnel through the tunnel dielectric layer 102 and enters into the graded silicon nitride layer 112, the increased potential barrier height of the top side of the graded silicon nitride layer 112 can prevent charges escaping to the barrier dielectric layer 106. Since the charges are transferred to adjacent deeper trapping levels in the bottom side of the graded silicon nitride layer 112 by lateral hopping, the back-tunneling possibility of the charges is also reduced, thus increasing the charge trapping efficiency of the graded silicon nitride layer 112.

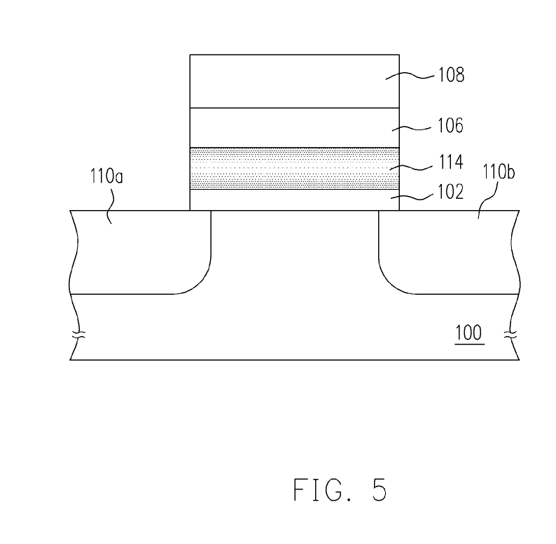

According to the third embodiment, the graded trapping layer 114 as shown in FIG. 5 is a two-stage graded layer, rather than a homogeneous layer of the same composition. The compositional ratio of the two-stage graded trapping layer 114 firstly becomes larger and then becomes smaller, from the bottom side (the side adjacent to the tunnel dielectric layer 102) to the top side (the side adjacent to the barrier dielectric layer 106). The graded trapping layer 114 is a two-stage graded silicon nitride layer (SiₓN_{y}) layer, for example. The silicon/nitrogen compositional ratio x/y of the two-stage graded silicon nitride layer firstly increases gradually and then decreases gradually, from the bottom side (the side adjacent to the tunnel dielectric layer 102) to the top side (the side adjacent to the barrier dielectric layer 106). The bottom side (the side adjacent to the tunnel dielectric layer 102) and the top side (the side adjacent to the barrier dielectric layer 106) of the two-stage graded silicon nitride layer 114 include nitrogen-rich silicon nitride, while the middle portion of the two-stage graded silicon nitride layer 114 includes silicon-rich silicon nitride. The silicon/nitrogen compositional ratio x/y of silicon-rich silicon nitride is larger than ¾, while the silicon/nitrogen compositional ratio x/y of nitrogen-rich silicon nitride is smaller than ¾.

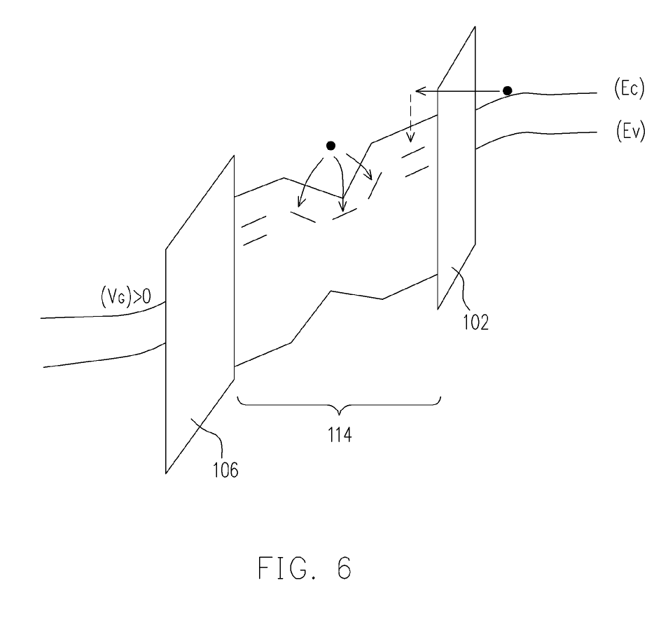

Because silicon nitride in the top side and bottom side of the two-stage graded silicon nitride layer 114 is nitrogen-rich silicon nitride, more trapping levels are available and accessible for charges. On the other hand, since silicon nitride in the middle portion of the two-stage graded silicon nitride layer 114 is silicon-rich silicon nitride, the potential barrier height is larger. Therefore, the graded silicon nitride layer 114 has a two-stage graded energy band gap. As shown in FIG. 6, as charges tunnel through the tunnel dielectric layer 102 and enters into the two-stage graded silicon nitride layer 114, due to the higher silicon content of silicon-rich silicon nitride in the middle portion of the graded silicon nitride layer 114, the large potential barrier height can prevent charges from tunneling to both the bottom side and the top side of the two-stage graded silicon nitride layer 114. Moreover, for charges tunneling to either the bottom side or the top side of the two-stage graded silicon nitride layer 114, charges are transferred to adjacent deeper trapping levels in the bottom side or the top side of the graded silicon nitride layer 114 by lateral hopping. Therefore, charges are trapped by the two-stage graded silicon nitride layer 114, thus increasing the charge trapping efficiency of the two-stage graded silicon nitride layer 114.

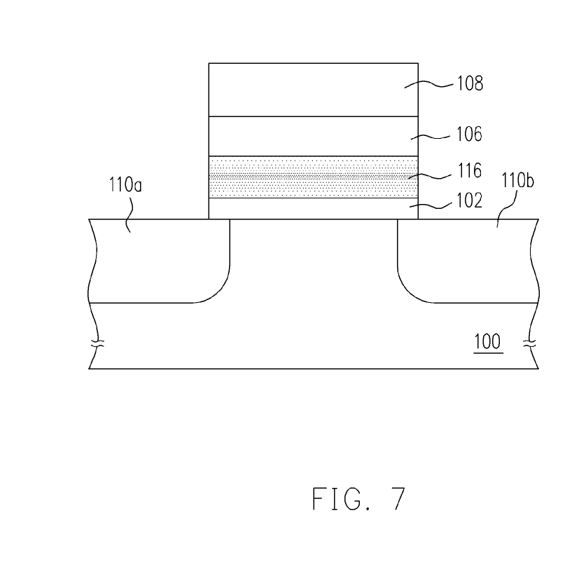

According to the fourth embodiment, the graded trapping layer 116 as shown in FIG. 7 is a two-stage graded layer, rather than a homogeneous layer of the same composition. The compositional ratio of the two-stage graded trapping layer 116 firstly becomes smaller and then becomes larger, from the bottom side (the side adjacent to the tunnel dielectric layer 102) to the top side (the side adjacent to the barrier dielectric layer 106). The graded trapping layer 116 is a two-stage graded silicon nitride layer (SiₓN_{y}) layer, for example. The silicon/nitrogen compositional ratio x/y of the two-stage graded silicon nitride layer firstly decreases gradually and then increases gradually, from the bottom side (the side adjacent to the tunnel dielectric layer 102) to the top side (the side adjacent to the barrier dielectric layer 106). The bottom side (the side adjacent to the tunnel dielectric layer 102) and the top side (the side adjacent to the barrier dielectric layer 106) of the two-stage graded silicon nitride layer 116 include silicon-rich silicon nitride, while the middle portion of the two-stage graded silicon nitride layer 116 includes nitrogen-rich silicon nitride. The silicon/nitrogen compositional ratio x/y of silicon-rich silicon nitride is larger than ¾, while the silicon/nitrogen compositional ratio x/y of nitrogen-rich silicon nitride is smaller than ¾.

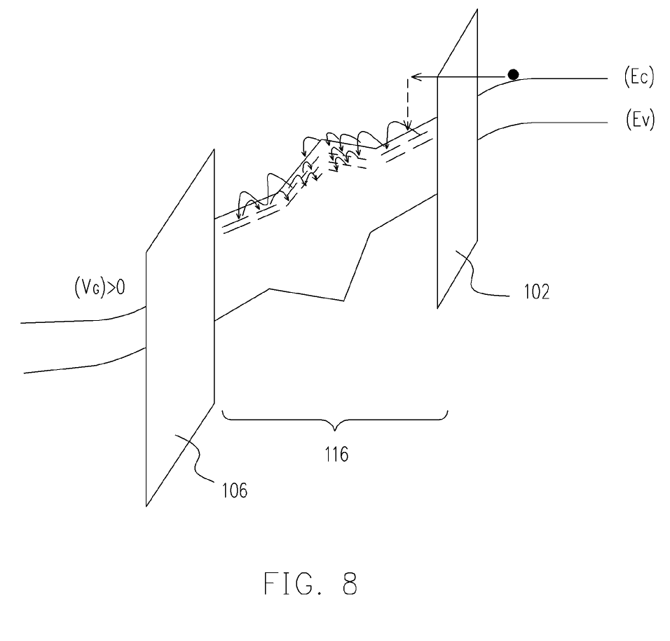

Because silicon nitride in the top side and bottom side of the two-stage graded silicon nitride layer 116 is silicon-rich silicon nitride, the potential barrier height is larger. On the other hand, since silicon nitride in the middle portion of the two-stage graded silicon nitride layer 116 is nitrogen-rich silicon nitride, more trapping levels are available and accessible for charges. Therefore, the graded silicon nitride layer 116 has a two-stage graded energy band gap. As shown in FIG. 8, as charges tunnel through the tunnel dielectric layer 102 and enters into the two-stage graded silicon nitride layer 116, charges can be easily trapped in the middle portion of the two-stage graded silicon nitride layer 116 due to more trapping levels available. Moreover, because of the higher silicon content of both the bottom side and the top side of the two-stage graded silicon nitride layer 116, the large potential barrier height can prevent charges from escaping through both the bottom side and the top side of the two-stage graded silicon nitride layer 116. Therefore, charges are trapped by the two-stage graded silicon nitride layer 116, thus increasing the charge trapping efficiency of the two-stage graded silicon nitride layer 116.

From the above embodiments, the silicon/nitrogen ratio of the silicon nitride trapping layer 104, 112, 114 or 116 varies, from one side of the trapping layer 104, 112, 114 or 116 adjacent to the tunnel dielectric layer 102 to another side of the trapping layer 104, 112, 114 or 116 adjacent to the barrier dielectric layer 106. As the silicon content of the trapping layer is increased (i.e. higher silicon/nitrogen ratio), the potential barrier is elevated so as to prevent charges escaping from the trapping layer. Also, by increasing the nitrogen content of the trapping layer (i.e. lower silicon/nitrogen ratio), more trapping levels are provided to enhance the charge trapping efficiency.

Hence, the graded trapping layers 104, 112, 114 and 116 as described herein can afford better charge trapping efficiency.

As long as the compositional ratio of the trapping layer varies from one side to another side (or from bottom to top), and the compositional ratio of the trapping layer changes as its position changes. The above embodiments are merely exemplary and not used to limit the scope of the present invention.

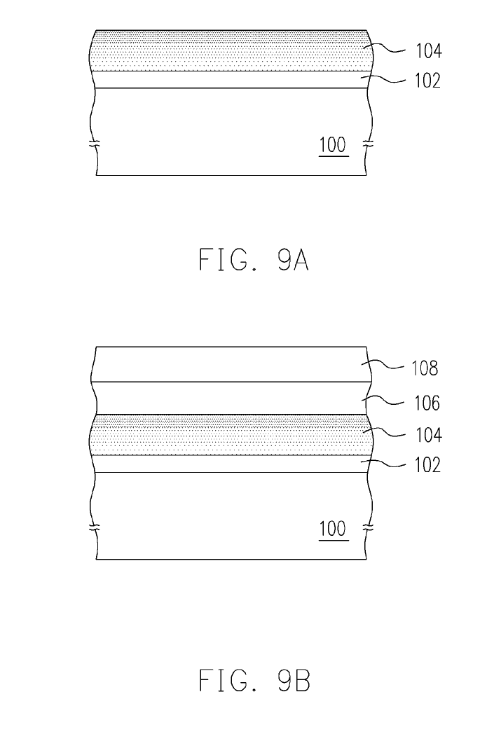

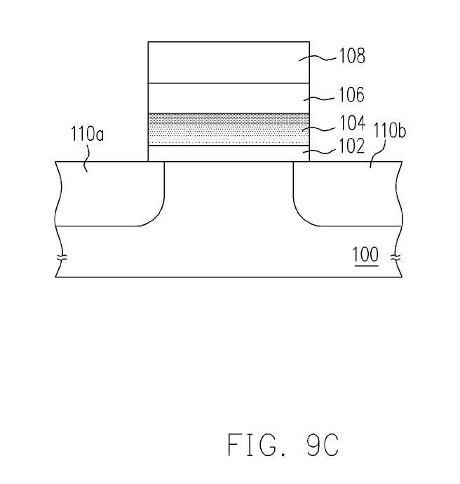

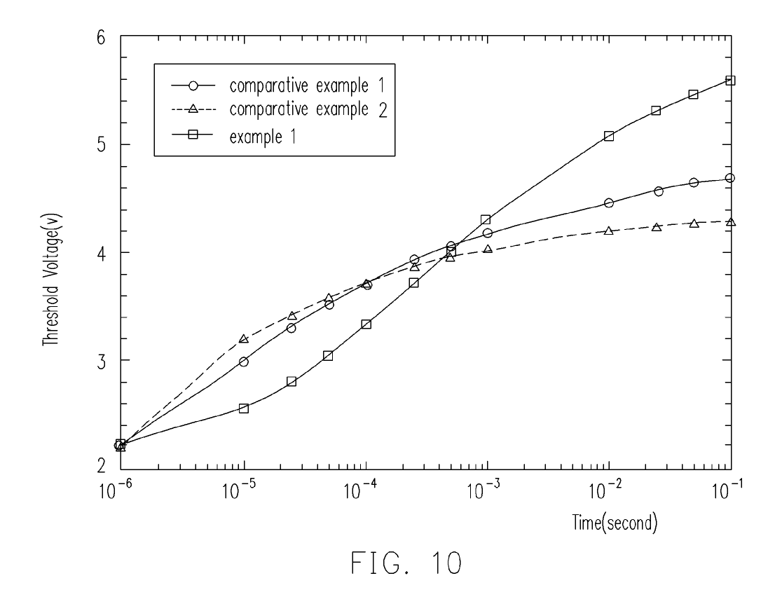

FIGS. 9A to 9C illustrates cross-sectional views of the process steps for forming a non-volatile memory cell according to one preferred embodiment of this invention.

Referring to FIG. 9A, a tunnel dielectric layer 102 is formed over a provided substrate 100. The substrate 100 is a P-type substrate or a N-type substrate, for example.

The tunnel dielectric layer 102 is, for example, is formed of silicon nitride by using N₂O as the reaction gas and then performing a thermal oxidation process.

Then, the graded trapping layer 104 is formed on the tunnel dielectric layer 102. The graded trapping layer 104 is formed by using several reactants, and these reactants are mixed in specific mixing ratios. By adjusting the mixing ratios of the reactants, the compositional ratios of the graded trapping layer can be controlled.

For example, the graded silicon nitride (SiₓN_{y}) trapping layer is formed by low-pressure chemical vapor deposition (LPCVD) and applied reactants includes silicon containing reactants (such as SiH₂Cl₂) and nitrogen containing reactants (such as NH₃). During the formation process, for example, the mixing ratio of silicon containing reactants (SiH₂Cl₂) and nitrogen containing reactants (NH₃) becomes smaller so as to obtain the graded silicon nitride trapping layer 104 having the bottom side (the side adjacent to the tunnel dielectric layer 102) of the graded silicon nitride layer 104 composed of silicon-rich silicon nitride and the top side (the side adjacent to the barrier dielectric layer 106) of the graded silicon nitride layer 104 composed of nitrogen-rich silicon nitride.

Generally, the flow rate of the silicon containing reactant (such as SiH₂Cl₂) is adjusted between 10%-90% of the maximum flow rate, while the flow rate of the nitrogen containing reactant (such as NH₃) is adjusted between 10%-90% of the maximum flow rate. For example, when the maximum flow rate of SIH₂Cl₂ is 200 sccm and the maximum flow rate of NH₃ is 500 sccm, the flow rate of SIH₂Cl₂ is variable between 20-180 sccm and the flow rate of NH₃ is variable between 20-450 sccm. Namely, during the formation process of the graded silicon nitride trapping layer, the mixing ratio (flow rate ratio) of SiH ₂Cl₂/NH₃ is about 180/50 for forming the most silicon-rich silicon nitride, while the mixing ratio (flow rate ratio) of SiH₂Cl₂ NH₃ is about 20/450 for forming the most nitrogen-rich silicon nitride.

Referring to FIG. 9B, the barrier dielectric layer 106 is formed on the graded trapping layer 104. The barrier dielectric layer 106 is, for example, made of silicon oxide by CVD using tetra-ethyl-ortho-silicate (TEOS) as reaction gas. Afterwards, a gate conductive layer 108 is formed on the barrier dielectric layer 106. The gate conductive layer 108 is made of doped polysilicon, for example. The method for forming the gate conductive layer 108 includes, for example, depositing an undoped polysilicon layer (not shown) by CVD and then performing implantation to the undoped polysilicon layer. Alternatively, the method for forming the gate conductive layer 108 can includes CVD with in-situ doping by flowing reaction gas such as PH₃ into the chamber.

Referring to FIG. 9C, after patterning the gate conductive layer 108, the barrier dielectric layer 106, the graded trapping layer 104 and the tunnel dielectric layer 102, source/drain regions 110a/110bare formed in the substrate 100 along both sides of the patterned gate conductive layer 108, thus completing the fabrication of the non-volatile memory cell. For example, an ion implantation step by using N-type dopants or P-type dopants is performed to form the source/drain regions 110a/110b.

For the graded trapping layer 104, 112, 114 and 116, the graded trapping layer can be formed by using several reactants in adjustable mixing ratios to control the compositional ratios of the graded trapping layer.

Taking the graded silicon nitride (SiₓN_{y}) trapping layer as an example, the graded silicon nitride (SiₓN_{y}) trapping layer is formed by using silicon containing reactants (such as SiH₂Cl₂) and nitrogen containing reactants (such as NH₃). During the formation process, according to the second embodiment, the mixing ratio of silicon containing reactants (SiH₂Cl₂) and nitrogen containing reactants (NH₃) becomes larger so as to obtain the graded silicon nitride trapping layer 112 having the bottom side (the side adjacent to the tunnel dielectric layer 102) of the graded silicon nitride layer 112 composed of nitrogen-rich silicon nitride and the top side (the side adjacent to the barrier dielectric layer 106) of the graded silicon nitride layer 112 composed of silicon-rich silicon nitride, as shown in FIG. 3.

In the third embodiment, the mixing ratio of silicon containing reactants (SiH₂Cl₂) and nitrogen containing reactants (NH₃) first increases and then decreases, so as to obtain the graded silicon nitride trapping layer 114 having the bottom side and the top side of the graded silicon nitride layer 114 composed of nitrogen-rich silicon nitride and the middle portion of the graded silicon nitride layer 114 composed of silicon-rich silicon nitride, as shown in FIG. 5.

In the fourth embodiment, the mixing ratio of silicon containing reactants (SiH₂Cl₂) and nitrogen containing reactants (NH₃) first decreases and then increases, so as to obtain the graded silicon nitride trapping layer 116 having the bottom side and the top side of the graded silicon nitride layer 116 composed of silicon-rich silicon nitride and the middle portion of the graded silicon nitride layer 116 composed of nitrogen-rich silicon nitride, as shown in FIG. 7.

The following data are provided to identify the characteristics of the non-volatile memory cell of this invention and to compare with the non-volatile memory cell of the prior art. Example 1: the non-volatile memory having the graded trapping layer 104 of FIG. 1 of this invention.

Comparative example 1: the prior art non-volatile memory having the trapping layer of the Si/N ratio equivalent to ¾. Comparative example 2: the prior art non-volatile memory having the silicon-rich trapping layer.

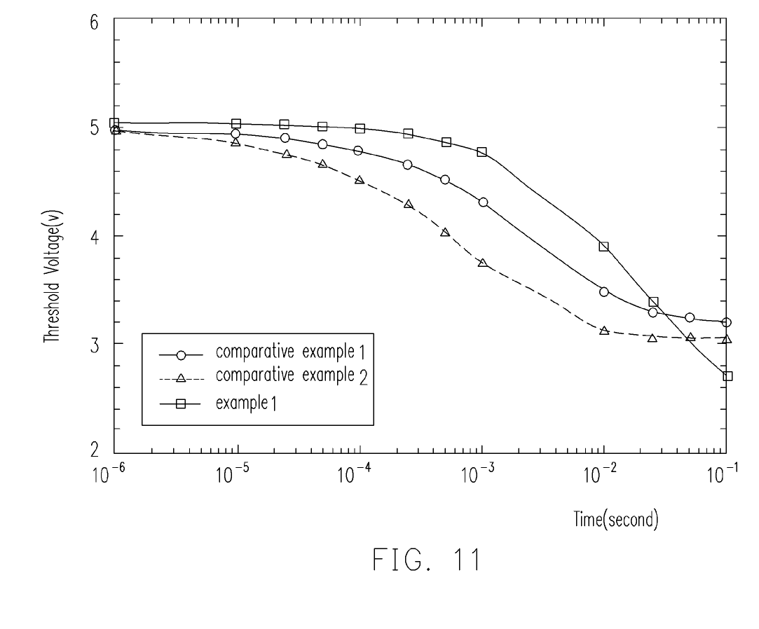

FIG. 10 is a graph showing the relation of threshold voltage (V) versus time (second) for the non-volatile memory, the Y axis indicating threshold voltage and X axis indicating time. Within the graph, the square, circle and triangle symbols represent example 1, comparative examples 1 and 2 respectively, after programming. As shown in FIG. 10, after programming, at about 10⁻³ seconds example 1 has the largest threshold voltage shift.

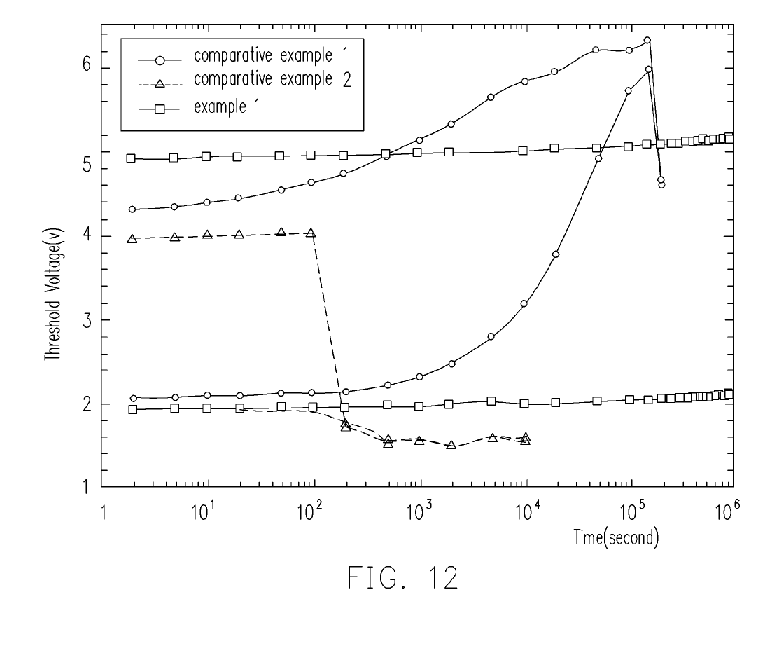

FIG. 11 is a graph showing the relation of threshold voltage (V) versus time (second) for the non-volatile memory, the Y axis indicating threshold voltage and X axis indicating time. Within the graph, the square, circle and triangle symbols represent example 1, comparative examples 1 and 2 respectively, after erasing. As shown in FIG. 11, after erasing, at about 10⁻² seconds example 1 has the reasonable threshold voltage shift.

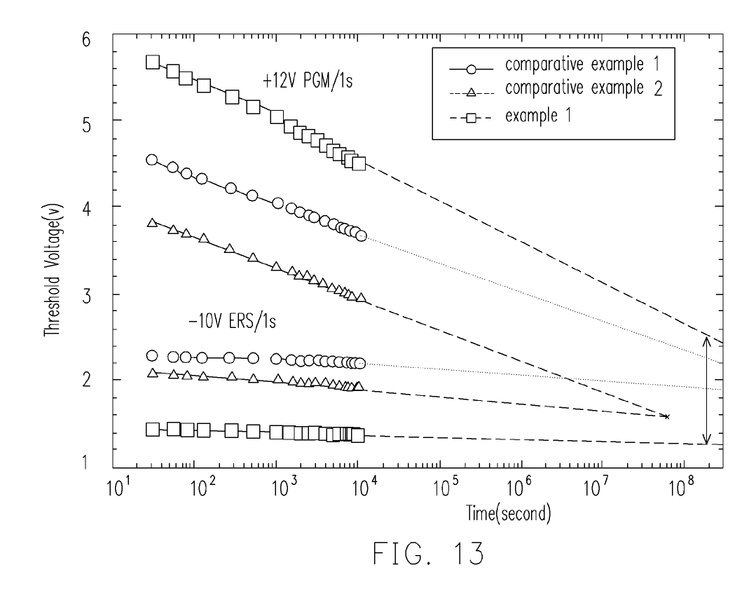

FIG. 12 is a graph showing the relation of threshold voltage (V) versus numbers of program/erase (P/E) cycles for the non-volatile memory, the Y axis indicating threshold voltage and X axis indicating numbers of P/E cycles.

Within the graph, the square, circle and triangle symbols in the upper portion represent example 1, comparative examples 1 and 2 respectively during programming, while the square, circle and triangle symbols in the lower portion represent example 1, comparative examples 1 and 2 respectively during erasing.

As shown in FIG. 12, the starting voltage detection window of the non-volatile memory relates to the threshold voltage difference between programming and erasing. Taking comparative examples as examples, the threshold voltage difference between programming and erasing is about 2V. However, for example 1 of this invention, the threshold voltage difference between programming and erasing is about 3V. Therefore, the non-volatile memory having a graded silicon-nitride trapping layer has a larger starting voltage detection window.

In addition, after about 100,000 P/E cycles, the non-volatile memory of comparative example 1 will lose the starting voltage detection window, thus losing programmability. The non-volatile memory of comparative example 2 will lose the starting voltage detection window after about 200 P/E cycles of operations. On the other hand, the starting voltage detection window of the non-volatile memory in example 1 remains about 3V even after one million P/E cycles of operations, showing significantly better endurance.

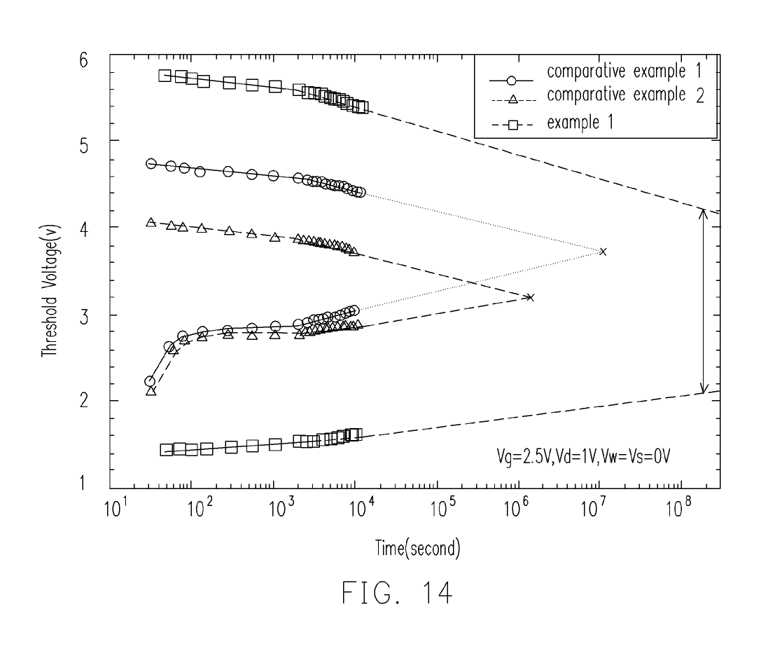

FIG. 13 is a graph showing the relation of threshold voltage (V) versus time (second) for the non-volatile memory, the Y axis indicating threshold voltage and X axis indicating time. Within the graph, the square, circle and triangle symbols in the upper portion represent example 1, comparative examples 1 and 2 respectively during programming, while the square, circle and triangle symbols in the lower portion represent example 1, comparative examples 1 and 2 respectively during erasing.

Referring to FIG. 13, as time increases, the threshold voltage is decreasing, thus reducing the starting voltage detection window for these three samples. For the non-volatile memory of comparative example 1, after 3×10⁸ seconds, the starting voltage detection window is about 0.3V, which may cause the non-volatile memory being not readable. For the non-volatile memory of comparative example 2, after 5×10⁷ seconds, the starting voltage detection window of the non-volatile memory even disappears, thus losing programmability. However, the non-volatile memory of this invention (example 1), after 3×10⁸ seconds, still has the starting voltage detection window of about 1.3V. Hence, the non-volatile memory of this invention has programmability even after 3×10⁸ seconds, thus having improved retention for the stored data (charges).

FIG. 14 is a graph showing the read-disturb characteristic for the three different nitride films non-volatile memory, the Y axis indicating threshold voltage and X axis indicating time. Within the graph, the square, circle and triangle symbols in the upper portion represent example 1, comparative examples 1 and 2 respectively read-disturb characteristic after programming, while the square, circle and triangle symbols in the lower portion represent example 1, comparative examples 1 and 2 respectively read-disturb characteristic after erasing.

Referring to FIG. 14, as time increases, the threshold voltage is decreasing similar to retention trend, thus reducing the starting voltage detection window for these three samples. For the non-volatile memory of comparative example 1, it is very sensitivity to read operation. Rising the threshold voltage of erase state very speedy and after 107 seconds, the starting voltage detection window is vanishing, which may cause the non-volatile memory being not readable. For the non-volatile memory of comparative example 2, it also cannot withstand the device read frequently. Raising the threshold voltage of erasing state very quickly and after 2×10⁶ seconds, the starting voltage detection window of the non-volatile memory even disappears, thus losing storage ability. However, the non-volatile memory of this invention (example 1), after 3×10 ⁸ seconds, still has the starting voltage detection window of about 2.1V. That is better than retention characteristic which in the brush aside situation. Hence, the non-volatile memory of this invention with a self-recovery mechanism of read operation that actually improves retention.

In conclusion, the present invention provides the following advantages.

1. The present invention employs a graded charge trapping layer for the non-volatile memory structure, which can effectively increase the charge trapping efficiency of the charge trapping layer and beneficial for the multiple-bit non-volatile memory.

2. Because the graded trapping layer applied herein provides better charge trapping efficiency, i.e. charges are easily trapped and unlikely to escape, the non-volatile memory structure disclosed in the present invention can allow larger starting voltage detection windows and afford better endurance, enhanced data storage retention, and improved read-disturb characteristic.

3. Compared with the thicker (about 450 Angstroms) trapping layer in the prior structure, the graded charge trapping layer of this invention is thinner (with a thickness of about 50 Angstroms) and has better charge trapping efficiency Hence, the non-volatile memory structure disclose in this invention can be operated under a lower operation voltage and with less power consumption.

4. According to the present invention, the graded charge trapping layer with high charge trapping efficiency is formed by adjusting the mixing ratios of the reactants. Therefore, the graded charge trapping layer of this invention can be fabricated by using the processes compatible with the prior art processes, which is cost-effective.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A non-volatile memory cell, comprising:
a tunnel dielectric layer disposed on a substrate;
a barrier dielectric layer disposed over the tunnel dielectric layer;
a graded charge trapping layer disposed between the barrier dielectric layer disposed and the tunnel dielectric layer, wherein a compositional ratio of the graded charge trapping layer varies from one side of the graded charge trapping layer adjacent to the tunnel dielectric layer to another opposite side of the graded charge trapping layer adjacent to the barrier dielectric layer;
a gate conductive layer disposed on the barrier dielectric layer;
a source region and a drain region respectively disposed in the substrate along both sides of the gate conductive layer.

2. The non-volatile memory cell as claimed in claim 1, wherein the compositional ratio of the graded charge trapping layer gradually decreases from one side of the graded charge trapping layer adjacent to the tunnel dielectric layer to another opposite side of the graded charge trapping layer adjacent to the barrier dielectric layer.

3. The non-volatile memory cell as claimed in claim 1, wherein the compositional ratio of the graded charge trapping layer gradually increases from one side of the graded charge trapping layer adjacent to the tunnel dielectric layer to another opposite side of the graded charge trapping layer adjacent to the barrier dielectric layer.

4. The non-volatile memory cell as claimed in claim 1, wherein the compositional ratio of the graded charge trapping layer first gradually increases and then gradually decreases, from one side of the graded charge trapping layer adjacent to the tunnel dielectric layer to another opposite side of the graded charge trapping layer adjacent to the barrier dielectric layer.

5. The non-volatile memory cell as claimed in claim 1, wherein the compositional ratio of the graded charge trapping layer first gradually decreases and then gradually increases, from one side of the graded charge trapping layer adjacent to the tunnel dielectric layer to another opposite side of the graded charge trapping layer adjacent to the barrier dielectric layer.

6. The non-volatile memory cell as claimed in claim 1, wherein the graded charge trapping layer is a graded silicon nitride (SiₓN_{y}) layer.

7. The non-volatile memory cell as claimed in claim 6, wherein the silicon/nitrogen ratio (x/y) of the graded charge trapping layer gradually decreases from one side of the graded charge trapping layer adjacent to the tunnel dielectric layer to another opposite side of the graded charge trapping layer adjacent to the barrier dielectric layer.

8. The non-volatile memory cell as claimed in claim 6, wherein the silicon/nitrogen ratio (x/y) of the graded charge trapping layer gradually increases from one side of the graded charge trapping layer adjacent to the tunnel dielectric layer to another opposite side of the graded charge trapping layer adjacent to the barrier dielectric layer.

9. The non-volatile memory cell as claimed in claim 6, wherein the silicon/nitrogen ratio (x/y) of the graded charge trapping layer first gradually increases and then gradually decreases, from one side of the graded charge trapping layer adjacent to the tunnel dielectric layer to another opposite side of the graded charge trapping layer adjacent to the barrier dielectric layer.

10. The non-volatile memory cell as claimed in claim 6, wherein the silicon/nitrogen ratio (x/y) of the graded charge trapping layer first gradually decreases and then gradually increases from one side of the graded charge trapping layer adjacent to the tunnel dielectric layer to another opposite side of the graded charge trapping layer adjacent to the barrier dielectric layer.

11. The non-volatile memory cell as claimed in claim 1, wherein a material of the tunnel dielectric layer includes silicon oxide.

12. The non-volatile memory cell as claimed in claim 1, wherein a material of the barrier dielectric layer includes silicon oxide.

13. A non-volatile memory cell, comprising:
a tunnel dielectric layer disposed over a substrate;
a barrier dielectric layer disposed over the tunnel dielectric layer;
a graded charge trapping layer disposed between the barrier dielectric layer disposed and the tunnel dielectric layer, wherein the graded charge trapping layer has a graded band gap and the graded band gap comprises of a plurality of trapping levels;
a gate conductive layer disposed on the barrier dielectric layer;
a source region and a drain region respectively disposed in the substrate along both sides of the gate conductive layer.

14. The non-volatile memory cell as claimed in claim 13, wherein the graded band gap of the graded charge trapping layer gradually decreases from one side of the graded charge trapping layer adjacent to the tunnel dielectric layer to another opposite side of the graded charge trapping layer adjacent to the barrier dielectric layer.

15. The non-volatile memory cell as claimed in claim 13, wherein the graded band gap of the graded charge trapping layer gradually increases from one side of the graded charge trapping layer adjacent to the tunnel dielectric layer to another opposite side of the graded charge trapping layer adjacent to the barrier dielectric layer.

16. The non-volatile memory cell as claimed in claim 13, wherein the graded band gap of the graded charge trapping layer first gradually increases and then gradually decreases, from one side of the graded charge trapping layer adjacent to the tunnel dielectric layer to another opposite side of the graded charge trapping layer adjacent to the barrier dielectric layer.

17. The non-volatile memory cell as claimed in claim 13, wherein the graded band gap of the graded charge trapping layer first gradually decreases and then gradually increases, from one side of the graded charge trapping layer adjacent to the tunnel dielectric layer to another opposite side of the graded charge trapping layer adjacent to the barrier dielectric layer.

18. The non-volatile memory cell as claimed in claim 13, wherein numbers of the trapping levels vary from one side of the graded charge trapping layer adjacent to the tunnel dielectric layer to another opposite side of the graded charge trapping layer adjacent to the barrier dielectric layer, and for different positions in the graded charge trapping layer, the position with less numbers of the trapping levels has a higher potential barrier.

19. The non-volatile memory cell as claimed in claim 13, wherein numbers of the trapping levels of the graded charge trapping layer gradually increases from one side of the graded charge trapping layer adjacent to the tunnel dielectric layer to another opposite side of the graded charge trapping layer adjacent to the barrier dielectric layer, and the one side of the graded charge trapping layer adjacent to the tunnel dielectric layer has a higher potential barrier.

20. The non-volatile memory cell as claimed in claim 13, wherein numbers of the trapping levels of the graded charge trapping layer gradually decreases from one side of the graded charge trapping layer adjacent to the tunnel dielectric layer to another opposite side of the graded charge trapping layer adjacent to the barrier dielectric layer, and the another side of the graded charge trapping layer adjacent to the barrier dielectric layer has a higher potential barrier.

21. The non-volatile memory cell as claimed in claim 13, wherein numbers of the trapping levels of the graded charge trapping layer first gradually increases and then gradually decreases, from one side of the graded charge trapping layer adjacent to the tunnel dielectric layer to another opposite side of the graded charge trapping layer adjacent to the barrier dielectric layer, and the both sides of the graded charge trapping layer have higher potential barriers.

22. The non-volatile memory cell as claimed in claim 13, wherein numbers of the trapping levels of the graded charge trapping layer first gradually decreases and then gradually increases, from one side of the graded charge trapping layer adjacent to the tunnel dielectric layer to another opposite side of the graded charge trapping layer adjacent to the barrier dielectric layer, and a middle portion of the graded charge trapping layer has a higher potential barrier.

23. The non-volatile memory cell as claimed in claim 13, wherein a material of the tunnel dielectric layer includes silicon oxide.

24. The non-volatile memory cell as claimed in claim 13, wherein a material of the barrier dielectric layer includes silicon oxide.

25. The non-volatile memory cell as claimed in claim 13, wherein the graded charge trapping layer is a graded silicon nitride (SiₓN_{y}) layer.
